(19) United States
(12) Patent Application Publication
(10) Pub. No.: US 2015/0008472 A1
(43) Pub. Date: Jan. 8, 2015

(54) Light Emitting Diode

(71) Applicant: Lextar Electronics Corporation, Hsinchu (TW)

(72) Inventor: Chia-Hsian CHOU, Taoyuan County (TW)

(73) Assignee: Lextar Electronics Corporation, Hsinchu (TW)

(21) Appl. No.: 14/141,449

(22) Filed: Dec. 27, 2013

(30) Foreign Application Priority Data
Jul. 3, 2013 (TW) 102123829

(51) Int. Cl. H01L 33/42; H01L 33/62

(52) U.S. Cl. CPC H01L 33/42; H01L 33/62
USPC 257/99

(57) ABSTRACT

A light emitting diode including a substrate, a first type semiconductor layer, a luminous layer, a second type semiconductor layer, a first electrode, a transparent conductive layer, and a second electrode. The first type semiconductor layer is disposed on the substrate. The luminous layer is disposed on a portion of the first type semiconductor layer. The second type semiconductor layer is disposed on the luminous layer. The first electrode is disposed on a portion of the first type semiconductor layer not covered by the luminous layer. The transparent conductive layer disposed on the second type semiconductor layer has a plurality of through holes exposing the surface of the second type semiconductor layer. The second electrode is disposed on the transparent conductive layer. The distribution density D1 of the through holes near the second electrode is different from the distribution density D2 of the through holes near the first electrode.

### RELATED APPLICATIONS

This application claims priority to Taiwan Application Serial Number 102123829, filed Jul. 3, 2013 which is herein incorporated by reference.

### BACKGROUND

1. Field of Invention

The present invention relates to light emitting diode.

2. Description of Related Art

A light emitting diode (LED) is a kind of luminous semiconductor device. The luminous layer generates photons to emit light by the recombination of holes and electrons in the semiconductor, Because LED has the advantages of small volume, long lifetime and power saving, it is widely utilized in display and illumination devices.

However, owing to material and manufacturing process of LED, the current distribution of the LED may be non-uniform during LED is energized. The current crowding may be happened in some region by the over concentration of current so that the illuminating efficiency of LED is decreased. Therefore, to improve the effect of the current crowding is an urgent issue for the industry.

### SUMMARY

One embodiment of this invention provides a light emitting diode including a substrate, a first type semiconductor layer, a luminous layer, a second type semiconductor layer, a first electrode, a transparent conductive layer, and a second electrode. The first type semiconductor layer is disposed on the substrate. The luminous layer is disposed on a portion of the first type semiconductor layer. The second type semiconductor layer is disposed on the luminous layer. The first electrode is disposed on a portion of the first type semiconductor layer not covered by the luminous layer. The transparent conductive layer is disposed on the second type semiconductor layer, and the transparent conductive layer has a plurality of through holes exposing the surface of the second type semiconductor layer. The second electrode is disposed on the transparent conductive layer. The vertical projections of the first electrode, the second electrode, and the through holes on the substrate shows the distribution density D1 of the through holes near the second electrode is different from the distribution density D2 of the through holes near the first electrode.

In one or more embodiments of this invention, D1 is larger than D2.

In one or more embodiments of this invention, D1 is smaller than D2.

Another embodiment of this invention provides a light emitting diode including a substrate, a first type semiconductor layer, a luminous layer, a second type semiconductor layer, a first electrode, a transparent conductive layer, and a second electrode. The first type semiconductor layer is disposed on the substrate. The luminous layer is disposed on a portion of the first type semiconductor layer. The second type semiconductor layer is disposed on the luminous layer. The first electrode is disposed on a portion of the first type semiconductor layer not covered by the luminous layer. The transparent conductive layer is disposed on the second type semiconductor layer, and the transparent conductive layer has a plurality of through holes exposing the surface of the second type semiconductor layer. The second electrode is disposed on the transparent conductive layer. The radiuses of the through holes are different. The vertical projections of the first electrode, the second electrode, and the through holes on the substrate shows the average radius R1 of the through holes near the second electrode is different from the average radius R2 of the through holes near the first electrode.

In one or more embodiments of this invention, R1 is larger than R2.

In one or more embodiments of this invention, R1 is smaller than R2.

In one or more embodiments of this invention, the material of the transparent layer may be one of ITO, ZnO, and IZO or a combination thereof.

In one or more embodiments of this invention, the first electrode has at least one first branch, the second electrode has at least one second branch, and the vertical projections of the first branch and the second branch on the substrate are alternately disposed.

In one or more embodiments of this invention, the first semiconductor layer is an N-type semiconductor layer and the second semiconductor layer is a P-type semiconductor layer.

In one or more embodiments of this invention, the first semiconductor layer is a P-type semiconductor layer and the second semiconductor layer is an N-type semiconductor layer.

As mentioned above, the transparent conductive layer has plural through holes, and the density of the distribution or the average radius of the through holes near the second electrode is different from those of the through holes near the first electrode. Therefore, the effect of the current crowding is improved.

### BRIEF DESCRIPTION OF THE DRAWINGS

FIG. 1 is a top view of the light emitting diode according to the first embodiment of this invention;

FIG. 2 is a cross-section view taken along line 2-2 in FIG. 1;

FIG. 3 is a top view of the light emitting diode according to the second embodiment of this invention;

FIG. 4 is a top view of the light emitting diode according to the third embodiment of this invention;

FIG. 5 is a cross-section view taken along line 5-5 in FIG. 4;

FIG. 6 is a top view of the light emitting diode according to the fourth embodiment of this invention;

FIG. 7 is a top view of the light emitting diode according to the fifth embodiment of this invention;

FIG. 8 is a top view of the light emitting diode according to the sixth embodiment of this invention;

FIG. 9 is a top view of the light emitting diode according to the seventh embodiment of this invention; and

FIG. 10 is a top view of the light emitting diode according to the eighth embodiment of this invention.

### DETAILED DESCRIPTION

Reference will now be made in detail to the present embodiments of the invention, examples of which are illustrated in the accompanying drawings. To clarify this invention, some details for practice may be described in some embodiments. However, these details should not limit this invention. In other words, the details may be not necessary for some other embodiments. To simplify the drawings, some conventional structures and devices are illustrated simply.

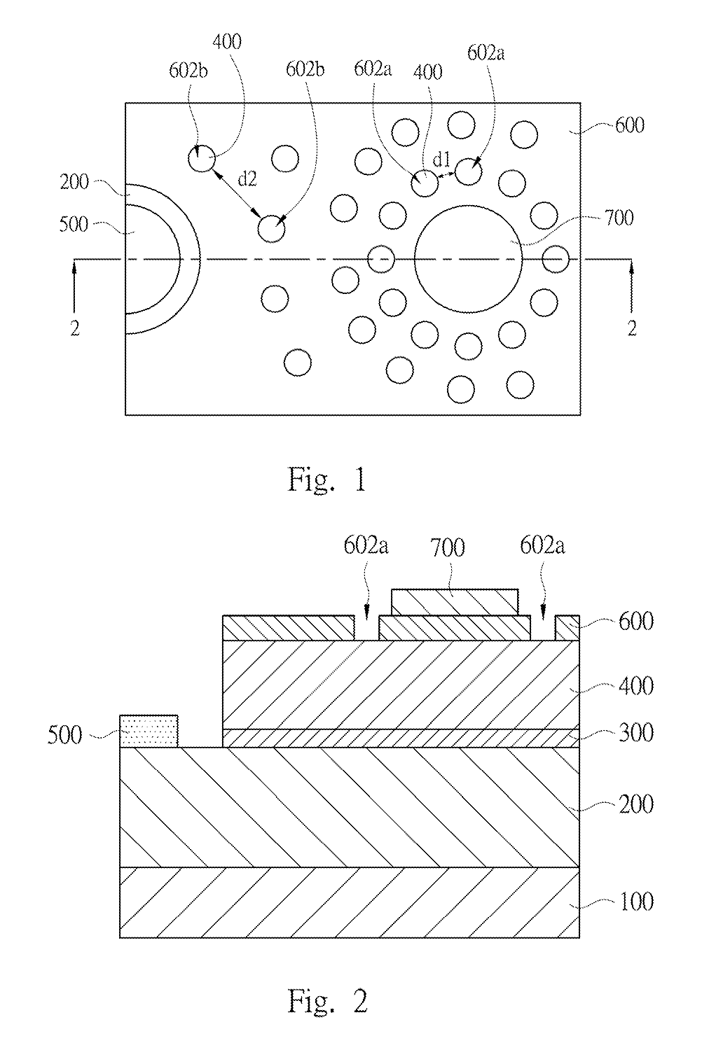

FIG. 1 is a top view of a light emitting diode according to the first embodiment of this invention. FIG. 2 is a cross-section view taken along line 2-2 of FIG. 1. Reference is made to FIGS. 1 and 2. The light emitting diode includes a substrate 100, a first type semiconductor layer 200, a luminous layer 300, a second type semiconductor layer 400, a first electrode 500, a transparent conductive layer 600, and a second electrode 700. The first type semiconductor layer 200 is disposed on the substrate 100. The luminous layer 300 is disposed on a portion of the first type semiconductor layer 200. The second type semiconductor layer 400 is disposed on the luminous layer 300. The first electrode 500 is disposed on a portion of the first type semiconductor layer 200 not covered by the luminous layer 300. The transparent conductive layer 600 is disposed on the second type semiconductor layer 400, and the transparent conductive layer 600 has a plurality of through holes 602a and 602b exposing the surface of the second type semiconductor layer 400. The second electrode 700 is disposed on the transparent conductive layer 600. The vertical projections of the first electrode 500, the second electrode 700, and the through holes 602a and 602b on the substrate 100 shows the distribution density D1 of the through holes 602a near the second electrode 700 is different from the distribution density D2 of the through holes 602b near the first electrode 500.

The density of the distribution is defined as the quantity of the through holes in a unit area of the transparent conductive layer 600. In this embodiment, the quantity of the through holes in a unit area near the second electrode 700 is larger than the quantity of the through holes in a unit area near the first electrode 500. Thus, the distribution density D1 is larger than the distribution density D2. In other words, more through holes are distributed near the second electrode 700. Furthermore, the distribution density of the through holes may be gradually increased as the area is closed to the second electrode 700. However, this invention is not limited to the distribution above. For example, for the vertical projection on the substrate 100, if there is no through hole on the shortest path between the through hole 602a and the second electrode 700, the through hole 602a is defined as the nearest through hole to the second electrode 700. A shortest distance d1 is defined as the distance between two adjacent through holes 602a. When the shortest distance d1 is smaller, the distribution of the through holes 602a is denser, that is, the quantity of the through holes in a unit area is larger and the distribution density D1 is larger. On the other hand, for the vertical projection on the substrate 100, if there is no through hole on the shortest path between the through hole 602b and the first electrode 500, the through hole 602b is defined as the nearest through hole to the first electrode 500. A shortest distance d2 is defined as the distance between two adjacent through holes 602b. When the shortest distance d2 is larger, the distribution of the through holes 602b is more dispersed, that is, the quantity of the through holes in a unit area is smaller and the distribution density D1 is smaller.

The through holes may affect the mobility of the current in the transparent conductive layer 600. For the transparent conductive layer 600, in the region with high distribution density of the through holes, the motion of the current is obstructed by the through holes. On the contrary, in the region far from the second electrode 700, the quantity of the through holes in the transparent conductive layer 600 is smaller, so that the mobility of the current is less affected by the through holes. Therefore, when the first electrode 500 and the second electrode 700 are energized, for example, the second electrode 700 is coupled to the anode, in the transparent conductive layer 600, most of the current may flow far from the second electrode 700 and near to the first electrode 500 (i.e., the current flows left in FIG. 2), and then the current may flow to the first electrode 500 through the second type semiconductor layer 400, the luminous layer 300, and the first type semiconductor layer 200.

The structure mentioned above can improve the current crowding effect of the light emitting diode. In greater detail, owing to material and manufacturing process of LED, the current distribution of LED may be non-uniform during LED is energized. The current crowding may be happened in some region by the over concentration of current, so that the illuminating efficiency of LED is decreased. In one or more embodiments, if the current crowding effect happens under the second electrode 700, LED of this invention may make the current flow far from the second electrode 700 in the transparent conductive layer 600 and then flow to the first electrode 500, so that the current crowding effect can be improved.

In this embodiment, the material of the transparent conductive layer 600 may be one of ITO (indium Tin Oxide), ZnO (Zinc Oxide) and IZO (Indium Zinc Oxide) or a combination thereof. The transparent conductive layer 600 helps the diffusion of the current, and the transparent characteristic thereof may not affect the illumination efficiency of LED. Furthermore, in one or more embodiments, the first type semiconductor layer 200 may be an N-type semiconductor layer and the second type semiconductor layer 400 may be a P-type semiconductor layer. However, in one or more other embodiments, the first type semiconductor layer 200 may be a P-type semiconductor layer and the second type semiconductor layer 400 may be an N-type semiconductor layer. This invention is not limited to these examples.

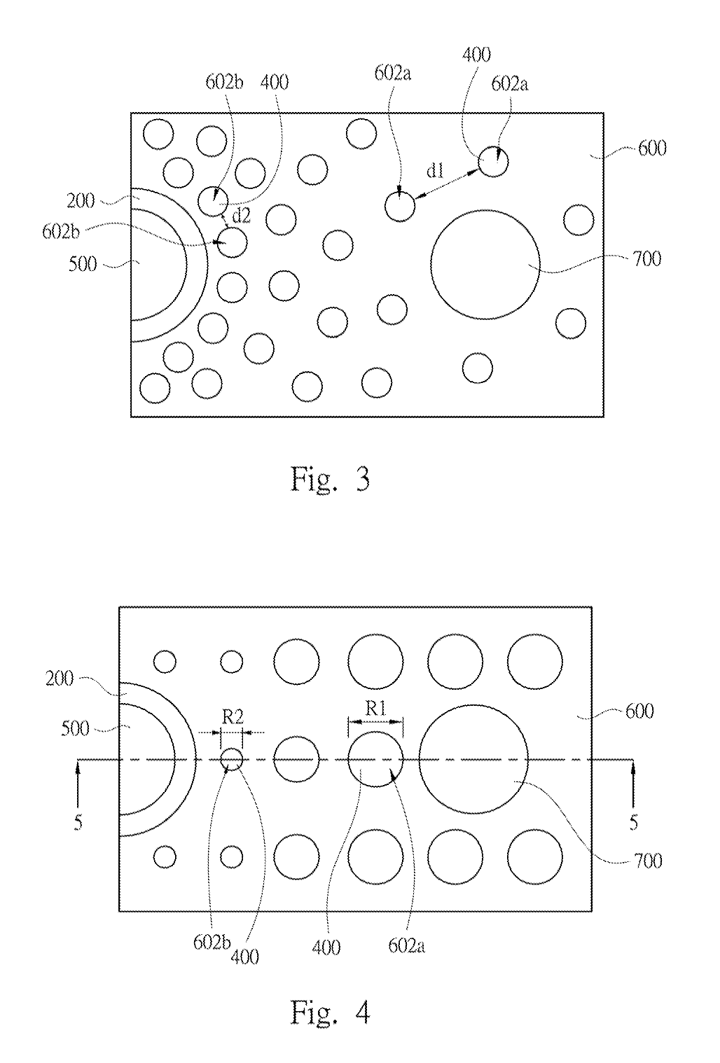

Reference is made to FIG. 3 which is a top view of the light emitting diode according to the second embodiment of this invention. The difference between the first embodiment and the second embodiment is the relation between the distribution density D1 and the distribution density D2. In this embodiment, the distribution density D1 is smaller than the distribution density D2. In other words, more through holes are distributed near the first electrode 500. In FIG. 3, the shortest distance d1 is larger than the shortest distance d2. Furthermore, the distribution density of through holes may be gradually decreased as the area is closed to the second electrode 700. However, this invention is not limited to the distribution above. Therefore, when the first electrode 500 and the second electrode 700 are energized, for example, the second electrode 700 is coupled to the anode, most of the current may flow downward to the first electrode 500 through the second type semiconductor layer 400, the luminous layer 300, and the first type semiconductor layer 200. If the current crowding effect happens under the first electrode 500, LED of this invention may improve the current crowding effect. The other parts of this embodiment are similar to the first embodiment, so those will not be described repeatedly herein.

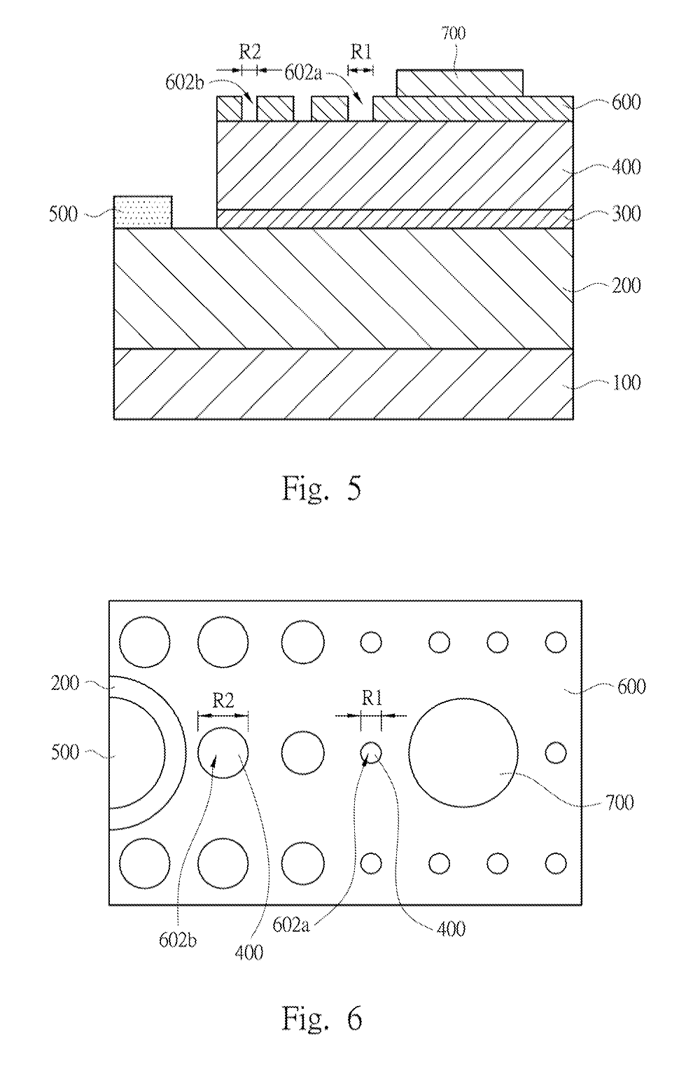

FIG. 4 is a top view of the light emitting diode according to the third embodiment of this invention, and FIG. 5 is a cross-section view taken along line 5-5 in FIG. 4. Reference is made to FIGS. 4 and 5. The differences between this embodiment and the first embodiment are the average radius and the distribution density of the through holes. In this embodiment, the distribution of the through holes is substantially uniform. However, the vertical projections of the first electrode 500, the second electrode 700, and the through holes 602a, 602b on the substrate 100 shows the average radius R1 of the through holes 602a near the second electrode 700 is different from the average radius R2 of the through holes 602b near the first electrode 500. For example, in FIG. 4, the average radius R1 is larger than the average radius R2. Furthermore, the average radius of through holes may be gradually increased as the area is closed to the second electrode 700. However, this invention is not limited to the distribution above.

The average radius of the through holes may affect the equivalent resistance distribution of the transparent conductive layer 600. For the transparent conductive layer 600, in the region with large radius of the through holes, the motion of the current is obstructed by the through holes. On the contrary, in the region far from the second electrode 700, the average radius of the through holes in the transparent conductive layer 600 is smaller, so that the mobility of the current is less affected by the through holes. Therefore, when the first electrode 500 and the second electrode 700 are energized, for example, the second electrode 700 is coupled to the anode, in the transparent conductive layer 600, most of the current may flow far from the second electrode 700 and near to the first electrode 500 (i.e., the current flows left in FIG. 5), and then the current may flow to the first electrode 500 through the second type semiconductor layer 400, the luminous layer 300, and the first type semiconductor layer 200.

The structure mentioned above can improve the current crowding effect of the light emitting diode. For example, if the current crowding effect happens under the second electrode 700, LED of this invention may make the current flow far from the second electrode 700 in the transparent conductive layer 600 and then flow to the first electrode 500, so that the current crowding effect can be improved. The other parts of this embodiment are similar to the first embodiment, so those will not be described repeatedly herein.

Reference is made to FIG. 6 which is a top view of the light emitting diode according to the fourth embodiment of this invention. The difference between the fourth embodiment and the third embodiment is the relation between the average radius R1 and the average radius R2. In this embodiment, the average radius R1 is smaller than the average radius R2. Furthermore, the average radius of through holes may be gradually decreased as the area is closed to the second electrode 700. However, this invention is not limited to the distribution above. Therefore, when the first electrode 500 and the second electrode 700 are energized, for example, the second electrode 700 is coupled to the anode, most of the current may flow to the second type semiconductor layer 400, the luminous layer 300 and the first type semiconductor layer 200 in sequence, and then the current flows to the first electrode 500. If the current crowding effect happens under the first electrode 500, LED of this invention may improve the current crowding effect. The other parts of this embodiment are similar to the third embodiment, so those will not be described repeatedly herein.

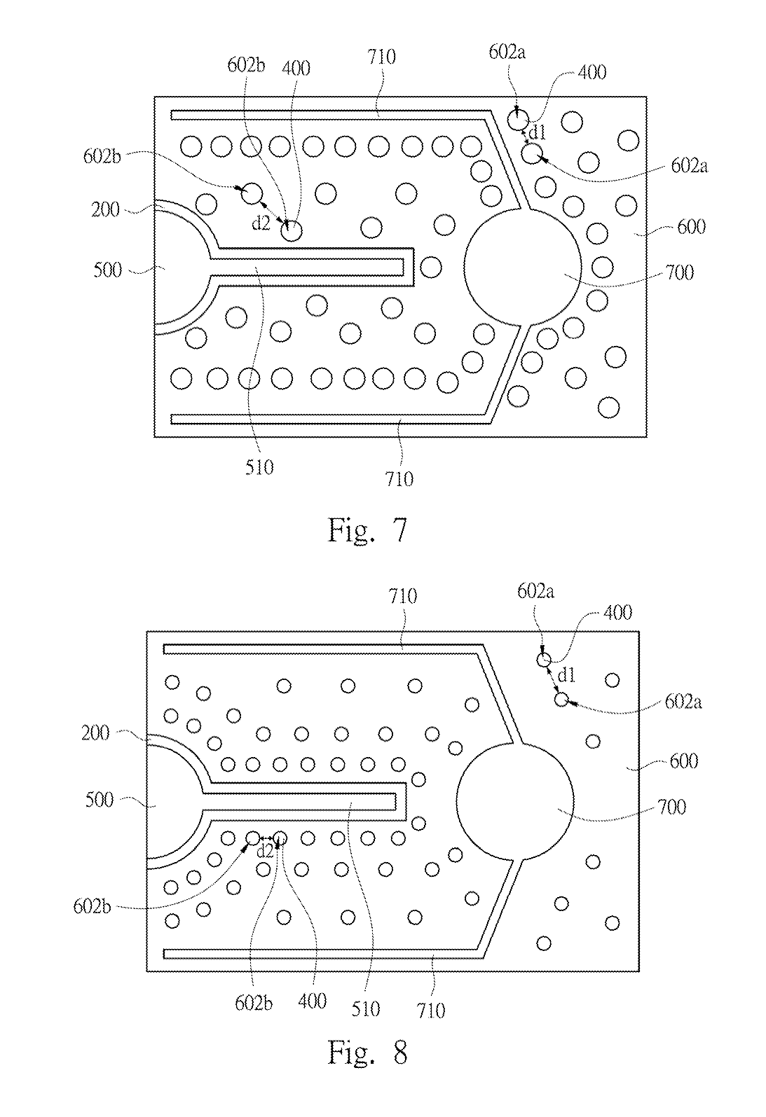

Reference is made to FIG. 7 which is a top view of the light emitting diode according to the fifth embodiment of this invention. The difference between the fifth embodiment and the first embodiment is the design of the first electrode 500 and the second electrode 700. In this embodiment, the first electrode 500 has at least one first branch 510. For example, there is one of the first branch 510 in FIG. 7. The second electrode 700 has at least one second branch 710. For example, there are two of the second branches 710 in FIG. 7. The vertical projections of the first branch 510 and the second branches 710 on the substrate 100 are alternately disposed. For example, in FIG. 7, the first branch 510 is disposed between the two second branches 710. The first branch 510 and the second branches 710 are utilized to increase the distribution space of the first electrode 500 and the second electrode 700. Thus, the current diffusion in the first type semiconductor layer 200 and the second type semiconductor layer 400 is enhanced, so that the illumination efficiency of the luminous layer 300 is improved.

In this embodiment, the through holes are distributed near the second electrode 700 and the second branches 710, so the distribution density D1 is larger than the distribution density D2. For example, for the vertical projection on the substrate 100, if there is no through hole on the shortest path between the through hole 602a and the second branch 710, the through hole 602a is defined as the nearest through hole to the second electrode 700 and the second branches 710. On the other hand, for the vertical projection on the substrate 100, if there is no through hole on the shortest path between the through hole 602b and the first branch 510, the through hole 602b is defined as the nearest through hole to the first electrode 500 and the first branch 510. As the example in FIG. 7, the shortest distance d1 is smaller than the shortest distance d2, such that the distribution of the through holes 602a is more concentrated than that of the through holes 602b. That is, the distribution density D1 is larger than the distribution density D2.

The LED of this embodiment not only improves the current crowding effect under the second electrode 700, but also improves that under the second branches 710. On the other hand, even the quantity of the first branch 510 is one and that of the second branches 710 is two, this invention is not limited to this design. A person having ordinary skills in the art may change the quantities of the first branch 510 and the second branch 710 according to real requirements. The other parts of this embodiment are similar to the first embodiment, so those will not be described repeatedly herein.

Reference is made to FIG. 8 which is a top view of the light emitting diode according to the sixth embodiment of this invention. The difference between the sixth embodiment and the fifth embodiment is the relation between the distribution density D1 and the distribution density D2. In this embodiment, the distribution density D1 is smaller than the distribution density D2. In other words, more through holes are distributed near the first electrode 500 and the first branch 510. That is, the shortest distance d1 is larger than the shortest distance d2. The LED of this embodiment not only improves the current crowding effect under the first electrode 500, but also improves that under the first branch 510. The other parts of this embodiment are similar to the fifth embodiment, so those will not be described repeatedly herein.

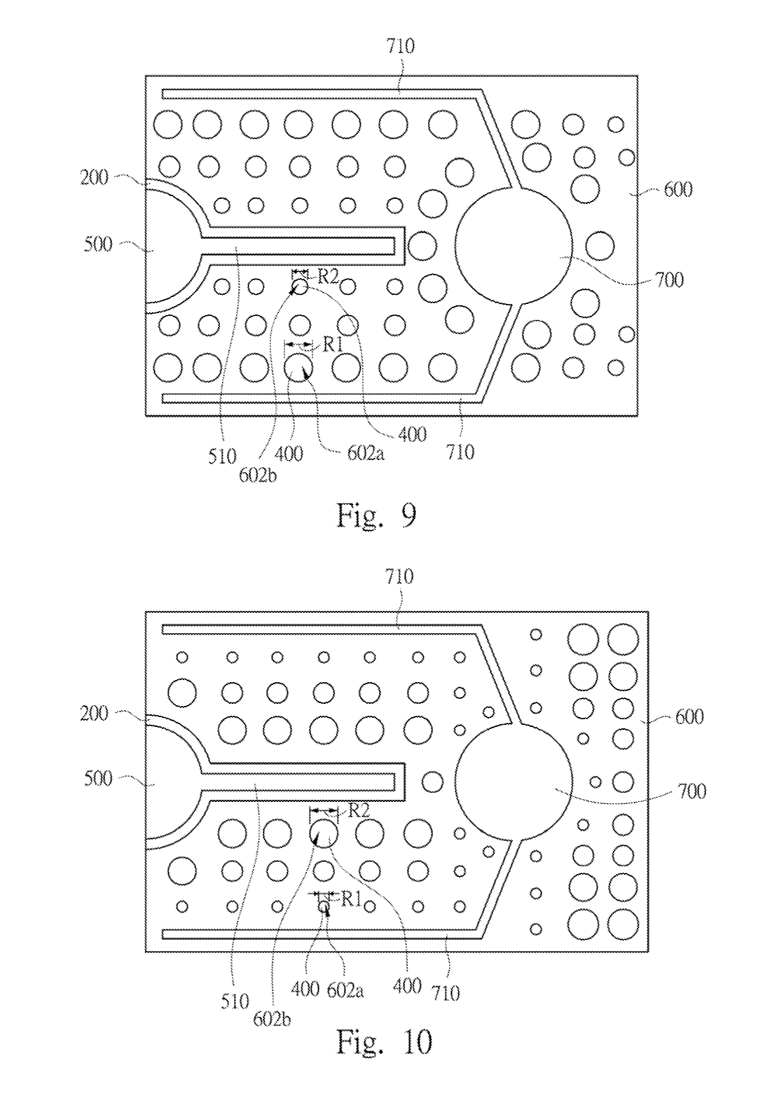

Reference is made to FIG. 9 which is a top view of the light emitting diode according to the seventh embodiment of this invention. The differences between this embodiment and the fifth embodiment are the average radius and the distribution density of the through holes. In this embodiment, the distribution of the through holes is substantially uniform. However, the vertical projections of the first electrode 500, the second electrode 700, and the through holes 602a, 602b on the substrate 100 shows the average radius R1 of the through holes 602a near the second electrode 700 is different from the average radius R2 of the through holes 602b near the first electrode 500. For example, in FIG. 9, the average radius R1 is larger than the average radius R2. Therefore, the LED of this embodiment not only improves the current crowding effect under the second electrode 700, but also improves that under the second branches 710. The other parts of this embodiment are similar to the fifth embodiment, so those will not be described repeatedly herein.

Reference is made to FIG. 10 which is a top view of the light emitting diode according to the eighth embodiment of this invention. The difference between the eighth embodiment and the seventh embodiment is the relation between the average radius R1 and the average radius R2. In this embodiment, the average radius R1 is smaller than the average radius R. Therefore, the LED of this embodiment not only improves the current crowding effect under the first electrode 500, but also improves that under the first branch 510. The other parts of this embodiment are similar to the third embodiment, so those will not be described repeatedly herein.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting diode, comprising:
a substrate;
a first type semiconductor layer disposed on the substrate;
a luminous layer disposed on a portion of the first type semiconductor layer;
a second type semiconductor layer disposed on the luminous layer;
a first electrode disposed on a portion of the first type semiconductor layer not covered by the luminous layer;
a transparent conductive layer disposed on the second type semiconductor layer, wherein the transparent conductive layer has a plurality of through holes exposing the surface of the second type semiconductor layer; and
a second electrode disposed on the transparent conductive layer,
wherein vertical projections of the first electrode, the second electrode, and the through holes on the substrate shows a distribution density D1 of the through holes near the second electrode is different from a distribution density D2 of the through holes near the first electrode.

2. The light emitting diode of claim 1, wherein D1 larger than D2.

3. The light emitting diode of claim 1, wherein D1 is smaller than D2.

4. The light emitting diode of claims 1, wherein the material of the transparent layer is one of ITO, ZnO, and IZO or a combination thereof.

5. The light emitting diode of claims 1, wherein the first electrode has at least one first branch, the second electrode has at least one second branch, and vertical projections of the first branch and the second branch on the substrate are alternately disposed.

6. The light emitting diode of claims 1, wherein the first type semiconductor layer is an N-type semiconductor layer and the second type semiconductor layer is a P-type semiconductor layer.

7. The light emitting diode of claims 1, wherein the first type semiconductor layer is a P-type semiconductor layer and the second type semiconductor layer is an N-type semiconductor layer.

8. A light emitting diode, comprising:
a substrate;
a first type semiconductor layer disposed on the substrate;
a luminous layer disposed on a portion of the first type semiconductor layer;
a second type semiconductor layer disposed on the luminous layer;
a first electrode disposed on a portion of the first type semiconductor layer not covered by the luminous layer;
a transparent conductive layer disposed on the second type semiconductor layer, wherein the transparent conductive layer has a plurality of through holes exposing the surface of the second type semiconductor layer; and
a second electrode disposed on the transparent conductive layer,
wherein radiuses of the through holes are different, and vertical projections of the first electrode, the second electrode, and the through holes on the substrate shows an average radius R1 of the through holes near the second electrode is different from an average radius R2 of the through holes near the first electrode.

9. The light emitting diode of claim 8, wherein R1 is larger than R2.

10. The light emitting diode of claim 8, wherein R1 smaller than R2.

11. The light emitting diode of claim 8, wherein the material of the transparent layer is one of ITO, ZnO, and IZO or a combination thereof.

12. The light emitting diode of claim 8, wherein the first electrode has at least one first branch, the second electrode has at least one second branch, and vertical projections of the first branch and the second branch on the substrate are alternately disposed.

13. The light emitting diode of claim 8, wherein the first type semiconductor layer is an N-type semiconductor layer and the second type semiconductor layer is a P-type semiconductor layer.

14. The light emitting diode of claim 8, wherein the first type semiconductor layer is a P-type semiconductor layer and the second type semiconductor layer is an N-type semiconductor layer.
